(19) United States
(12) Patent Application Publication
(10) Pub. No.: US 2013/0273744 A1
(43) Pub. Date: Oct. 17, 2013

(54) SUBSTRATE PROCESSING METHOD AND SUBSTRATE PROCESSING APPARATUS

(71) Applicant: KABUSHIKI KAISHA TOSHIBA, Tokyo (JP)

(72) Inventors: Hiroaki YAMADA, Yokkaichi (JP); Hiroyasu IIMORI, Mie-gun (JP); Junichi IGARASHI, Nagoya (JP)

(73) Assignee: KABUSHIKI KAISHA TOSHIBA, Tokyo (JP)

(21) Appl. No.: 13/788,121

(22) Filed: Mar. 7, 2013

(30) Foreign Application Priority Data
Apr. 12, 2012 (JP) 2012-091051

(51) Int. Cl. H01L 21/324

(52) U.S. Cl. CPC H01L 21/324
USPC 438/746; 156/345.11

(57) ABSTRACT

A method of processing a substrate is disclosed. The method uses a substrate processing apparatus including a processing tank that retains a processing liquid and that accommodates a workpiece substrate, a recirculation system recirculating the processing liquid into the processing tank by supplying the processing liquid heated by a recirculation system heater from a lower portion of the processing tank and collecting the processing liquid from an upper portion of the processing tank, a plurality of heaters distributed on an upper portion and a lower portion of the processing tank to heat the processing liquid. The method includes setting a first temperature setpoint to a heater located on the upper portion of the processing tank, and setting a second temperature setpoint lower than the first temperature setpoint to a heater located on the lower portion of the processing tank.

### CROSS-REFERENCE TO RELATED APPLICATION(S)

This application is based upon and claims the benefit of priority from Japanese Patent Application No. 2012-091051, filed on, Apr. 12, 2012 the entire contents of which are incorporated herein by reference.

### FIELD

Embodiments disclosed herein generally relate to a substrate processing method and a substrate processing apparatus.

### BACKGROUND

A wet etching process of wafers such as semiconductor substrates is typically carried out by immersing the wafer in wet etchant which is retained in a processing tank of a wet etching apparatus and heating the wet etchant with heater to an optimal temperature. The wet etchant is designed to overflow from the processing tank so that the overflow is collected and recirculated into the processing tank after heating and filtration.

One problem encountered in the above described etching process is the difficulty in retaining the wet etchant within the processing tank at an even temperature. Uneveness in the temperature of the wet etchant within the processing tank causes uneven etching of the wafer immersed in the wet etchant.

In one embodiment, a method of processing a substrate is disclosed. The method uses a substrate processing apparatus including a processing tank that retains a processing liquid and that accommodates a workpiece substrate, a recirculation system recirculating the processing liquid into the processing tank by supplying the processing liquid heated by a recirculation system heater from a lower portion of the processing tank and collecting the processing liquid from an upper portion of the processing tank, a plurality of heaters distributed on an upper portion and a lower portion of the processing tank to heat the processing liquid. The method includes setting a first temperature setpoint to a heater located on the upper portion of the processing tank, and setting a second temperature setpoint lower than the first temperature setpoint to a heater located on the lower portion of the processing tank.

### BRIEF DESCRIPTION OF THE DRAWINGS

FIG. 1 is a schematic view of the entire configuration of a first embodiment.

FIG. 2 is a schematic view of the entire configuration of a second embodiment.

FIG. 3 pertains to a third embodiment and indicates the variation in the temperature of a processing liquid with time.

FIG. 4 pertains to a fourth embodiment and illustrates the position in which the wafer is immersed.

### DESCRIPTION

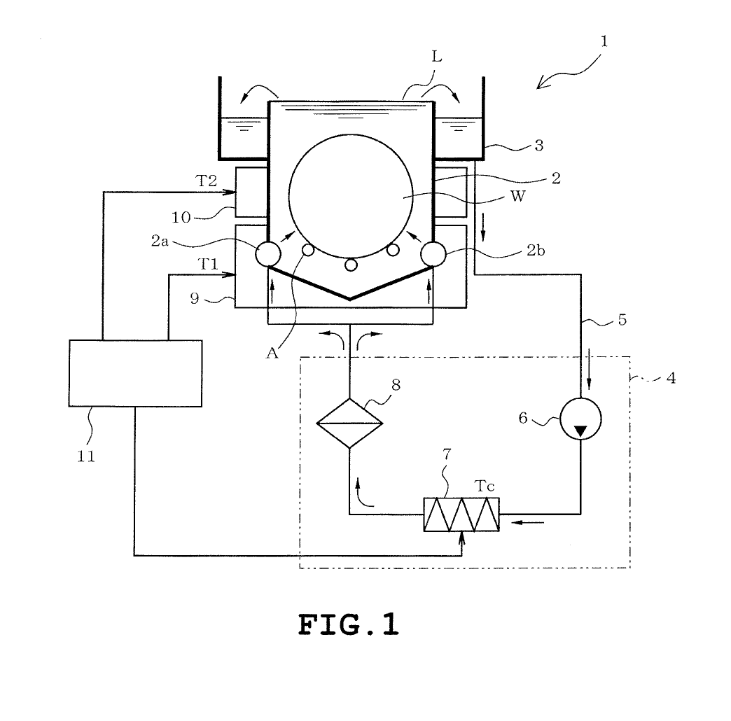

Referring to FIG. 1, a first embodiment is described hereinafter through an example of an etching apparatus. In this example, a silicon nitride film formed above a silicon substrate is etched by a wet etchant, or more generally, a processing liquid comprising hot phosphoric acid solution.

Etching apparatus 1, which is one example of a substrate processing apparatus, employs hot phosphoric acid solution L as the processing liquid. Hot phosphoric acid solution L is a heated mixture of phosphoric acid and purified water. In this example, the workpiece is a semiconductor substrate, more specifically, a silicon substrate which is hereinafter referred to as wafer W. Above the surface of wafer W, a silicon nitride film is formed which is etched as described herein. Using etching apparatus 1, wafer W is immersed in hot phosphoric acid solution L to wet etch the silicon nitride film. Wet etching apparatus 1 is provided with processing tank 2 for retaining hot phosphoric acid solution L. Processing tank 2 is made, for instance, of quartz glass and is configured in a volume that allows immersion of multiple wafers W placed on wafer lifter A. Wafer lifter A is one example of a wafer placement.

On the upper peripheral portion of processing tank 2, collecting receptacle 3 is provided for collecting hot phosphoric acid solution L overflowing from the upper portion of processing tank 2. Collecting receptacle 3 stores the collected hot phosphoric acid solution L so as not to overflow from it. The collected hot phosphoric acid solution L is thereafter passed through recirculation system 4 which communicates with the bottom opening of collecting receptacle 3 and is recirculated back into processing tank 2. At two opposing bottom ends of processing tank 2, discharge tubes 2a and 2b are provided to allow the collected hot phosphoric acid solution L to be discharged into processing tank 2. Discharge tubes 2a and 2b each have multiple discharge ports formed at predetermined spacing in the direction normal to the page of FIG. 1. The discharge ports of discharge tubes 2a and 2b are oriented such that hot phosphoric acid solution L is discharged toward the substantial center of processing tank 2.

Recirculation system 4 is provided with recirculation piping 5 which connects the bottom opening of collecting receptacle 3 with discharge tubes 2a and 2b located at the bottom of processing tank 2. As recirculation piping 5 extends from the bottom opening of collecting receptacle 3 to discharge tubes 2a and 2b of processing tank 2, recirculation piping 5 passes through recirculation pump 6, recirculation system heater 7, and percolating filter 8. Recirculation pump 6 sucks hot phosphoric acid solution L within collecting receptacle 3 from the bottom opening of collecting receptacle 3 and sends it to recirculation system heater 7. When hot phosphoric acid solution L sent from recirculation pump 6 flows through recirculation system heater 7, recirculation system heater 7 heats hot phosphoric acid solution L to temperature setpoint Tc. The temperature of hot phosphoric acid solution L is monitored by a thermocouple not shown provided within a portion of recirculation piping 5 that extends through recirculation system heater 7. Percolating filter 8 removes particles from the incoming hot phosphoric acid solution L from recirculation system heater 7 to achieve a certain cleanness level and thereafter returns the filtered hot phosphoric acid solution L toward processing tank 2.

Processing tank 2 is provided with multiple heaters for heating hot phosphoric acid solution L inside it. In the first embodiment, processing tank 2 is provided with 2 heaters namely, first tank heater 9 and second tank heater 10. First tank heater 9 and second tank heater 10 may each comprise a rubber heater or a crystal heater and are wound around the outer periphery of processing tank 2. First tank heater 9 and second tank heater 10 heat the processing liquid, in this example, hot phosphoric acid solution L within processing tank 2 and can be controlled independently. More specifically, first tank heater 9 is controlled to heat hot phosphoric acid solution L to temperature setpoint T1, whereas second tank heater 10 is controlled to heat hot phosphoric acid solution L to temperature setpoint T2. First and second tank heaters 9 and 10 are used to return the temperature of hot phosphoric acid solution L to a predetermined temperature from the temperature variation caused, for instance, by disturbances such as immersion of wafer W into hot phosphoric acid solution L within processing tank 2 and to maintain the predetermined temperature. First tank heater 9 is disposed so as to apply heat on the lower portion and the bottom surface portion of processing tank 2. Second tank heater 10 is disposed above first tank heater 9 and applies heat on hot phosphoric acid solution L within processing tank 2. Inside processing tank 2, a thermocouple not shown is provided near each of first tank heater 9 and second tank heater 10 in order to monitor the heating performed by first tank heater 9 and second tank heater 10. Recirculation system heater 7, first tank heater 9 and second tank heater 10 are coupled to heater controller 11 serving as a controller. Heater controller 11 controls the temperature of hot phosphoric acid solution L to temperature setpoint Tc, temperature setpoint T1, and temperature setpoint T2, through recirculation system heater 7, first tank heater 9, and second tank heater 10.

The above described wafer lifter A allows placement of the wafer W and is configured to hold the wafer with 3 bars. Wafer lifter A allows placement of up to approximately 50 wafers W. Wafer lifter A can be raised and lowered by an arm not shown and the position of wafer lifter A is controlled between an upper position above processing tank 2 and a predetermined position in which wafer lifter A is immersed in hot phosphoric acid solution L within processing tank 2.

Next, a description will be given on how the silicon nitride film formed above the surface of wafer W is etched using the above described etching apparatus 1.

As mentioned, processing tank 2 retains hot phosphoric acid solution L and receives supply of hot phosphoric acid solution L from discharge tubes 2a and 2b. Hot phosphoric acid solution L overflowing from the upper portion of processing tank 2 flows into collecting receptacle 3 and is pumped, by recirculation pump 6, into recirculation piping 5 of recirculation system 4. Recirculation system 4 carries hot phosphoric acid solution L through recirculation piping 5 and recirculates it back into processing tank 2 through discharge tubes 2a and 2b after re-heating it to temperature setpoint Tc by recirculation system heater 7 and filtering it through percolation filter 8.

Next a description will be given on how temperature is controlled when etching the silicon nitride film overlying wafer W being immersed in processing tank 2.

The description is given through an example in which the processing temperature of wafer W, in other words, the target temperature of hot phosphoric acid solution L in which wafer W is etched, is 160 degrees Celsius. Hot phosphoric acid solution L recirculated through recirculation system 4 is discharged toward a bottom central portion of processing tank 2 located slightly above discharge tubes 2a and 2b. The discharged hot phosphoric acid solution L tends to stay at the bottom central portion of processing tank 2.

During wet etching, the temperature of hot phosphoric acid solution L within processing tank 2 is monitored with the exception of hot phosphoric acid solution L located in the bottom central portion of processing tank 2. Based on the monitored temperature, first and second tank heaters 9 and 10 are controlled so that hot phosphoric acid solution L stays at a predetermined temperature. As mentioned, the discharged hot phosphoric acid solution L tends to stay at the bottom central portion of processing tank 2. Thus, if the temperature of the discharged hot phosphoric acid solution L is relatively high, and temperature both setpoints T1 and T2 are set to the processing temperature, the bottom central portion of processing tank 2 is occupied by a resident hot phosphoric acid solution L having a relatively high temperature. As a result, the silicon nitride film overlying the lower portion of wafer W immersed in processing tank 2 is exposed to hot phosphoric acid solution L of relatively high temperature and thus, is over etched as compared to other portions of wafer W.

The first embodiment addresses this problem through the control executed by heater controller 11. More specifically, heater controller 11 sets temperature setpoint T2 of second tank heater 10 at 160 degrees Celsius which equals the processing temperature of wafer W. On the other hand, heater controller 11 further sets temperature setpoint T1 of first tank heater 9 at 159 degrees Celsius which is lower than temperature setpoint T2. Heat controller 11 controls the heating of the bath of hot phosphoric acid solution L within processing tank 2 under the above described conditions. This prevents hot phosphoric acid solution L staying at the bottom central portion of processing tank 2 interior from keeping its relatively high temperature. As a result, the lower portion of wafer W, being immersed in processing tank 2, is no longer exposed to hot phosphoric acid solution L having relatively high temperature. This allows wafer W to be evenly exposed to a bath of hot phosphoric acid solution L of uniform temperature, thereby suppressing the variation in the etch amount of the silicon nitride film.

As an alternative to the above described approach, heater controller 11 may set temperature setpoint Tc of recirculation system heater 7 in recirculation system 4 at a slightly lower temperature level as compared to the temperature in which wafer W is processed. For instance, temperature setpoint Tc of recirculation system heater 7 may be set so as to be within the range of 0.5 to 1.5 degrees Celsius below the processing temperature of wafer W, in other words, the temperature of processing liquid within processing tank 2. Temperature setpoint Tc may be varied within the above described range depending upon the volume and the shape of processing tank 2 or the number of wafers W being processed, or the like. In this alternative approach, hot phosphoric acid solution L which was heated to a slightly lower temperature as compared to the processing temperature of wafer W is recirculated into processing tank 2. The temperature of hot phosphoric acid solution L within processing tank 2 is maintained at the processing temperature of wafer W by first and second tank heaters 9 and 10. Thus, the alternative approach suppresses the temperature elevation of resident hot phosphoric acid solution L at the bottom central portion of processing tank 2 more effectively.

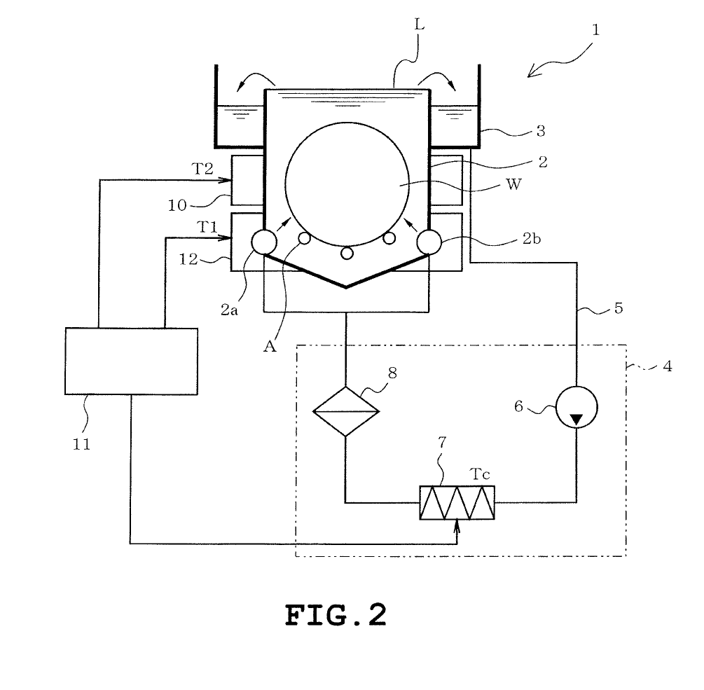

FIG. 2 illustrates a second embodiment which will be described hereinafter with an emphasis on the differences from the first embodiment. In the second embodiment, first tank heater 9 is replaced by first tank heater 12. First tank heater 12 is applied to processing tank 2 so as to be wound on the outer periphery of the lower sidewall of the processing tank 2 but is arranged so as not to be applied on the bottom surface portion of processing tank 2.

As mentioned earlier, hot phosphoric acid solution L tends to stay at the bottom central portion within processing tank 2 and thus, this portion of processing tank 2 tends to have elevated temperatures. Responsively, first tank heater 12 is configured so as not to apply heat from the bottom side of processing tank 2. Thus, the resident hot phosphoric acid solution L at the bottom central portion of processing tank 2 interior is not heated in the manner in which other portions of processing tank 2 are heated. As a result, local temperature elevation is suppressed.

The above described second embodiment also achieves the effects similar to those of the first embodiment and suppresses temperature variation more effectively.

The second embodiment may also be configured to set temperature setpoint Tc at a temperature level lower than the processing temperature of wafer W, taking into account the expected loss of heat applied from the bottom side of processing tank 2 by the absence of heater at the bottom of processing tank 2.

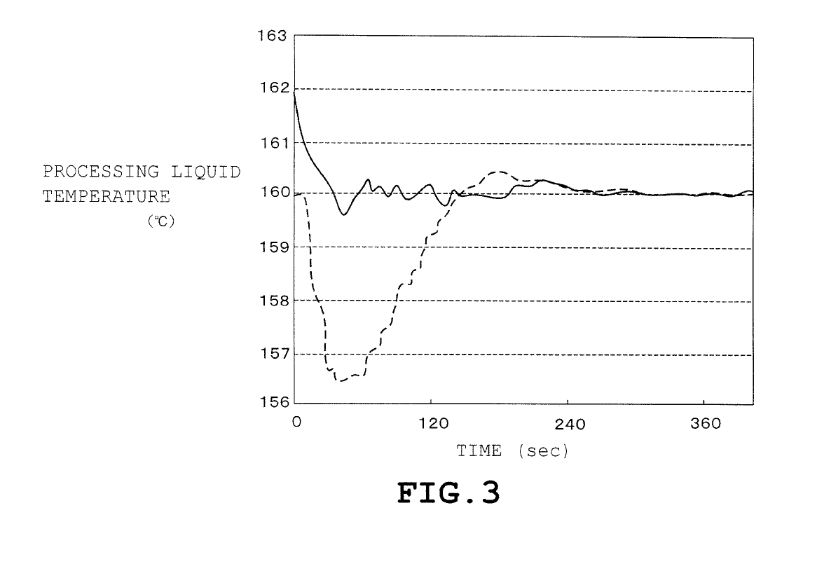

Next a description will be given on a third embodiment with reference to FIG. 3. In the third embodiment, a method of processing a substrate is described through a method of etching a substrate using etching apparatus 1 described in the first embodiment or the second embodiment.

Etching apparatus 1 of the foregoing embodiments etches the silicon nitride film with the bath of hot phosphoric acid solution L within processing tank 2 heated to the temperature of 160 degrees Celsius which is also referred to as the process temperature or wafer processing temperature. The temperature of the hot phosphoric acid solution L experiences a sudden and significant drop when large number of wafers W are immersed in the bath of hot phosphoric acid solution L that differ significantly in temperature from hot phosphoric acid solution L.

For example, FIG. 3 is a chart indicating the case in which 50 wafers W carried by wafer lifter A are immersed in hot phosphoric acid solution L. As indicated by broken line in FIG. 3, the temperature of hot phosphoric acid solution L drops significantly by approximately 3.5 degrees Celsius in the first minute after the immersion of wafers W. Then the temperature of hot phosphoric acid solution L, thereafter being heated by first tank heaters 9 and 10 or heaters 10 and 12 as the case may be, returns to 160 degrees Celsius after approximately 3 minutes from the immersion of wafers W.

Responsively, the temperature of hot phosphoric acid solution L is preemptively controlled to a temperature level slightly higher than the processing temperature of wafer W in anticipation of such temperature variation to allow recovery of the drop by, for example, 3.5 degrees Celsius. In this example, temperature setpoints T1 and T2 are set so that the temperature level of hot phosphoric acid solution L becomes higher than the wafer W processing temperature of 160 degrees Celsius by 2 to 3.5 degrees Celsius as indicated by the solid line in FIG. 3. Then, after the immersion of wafer W, temperature setpoints T1 and T2 are controlled to return to their original temperature setpoints of 159 degrees Celsius and 160 degrees Celsius. This control may be automated and synchronized with the descent of wafer lifter A or may be executed by manual operation.

Thus, the temperature of hot phosphoric acid solution L, being lowered immediately after immersion of 50 wafers W, promptly returns to nearly 160 degrees Celsius after showing a trajectory of temperature variation indicated by solid line in FIG. 3 because of the preemptive temperature elevation of hot phosphoric acid solution L in anticipation of the temperature drop to compensate for the thermal capacity of 50 wafers W. Further, because temperature setpoints T1 and T2 are returned to 159 degrees Celsius and 160 degrees Celsius respectively after the immersion of wafers W, the temperature of hot phosphoric acid solution L can be maintained at nearly 160 degrees Celsius by the controls already described. The method described above also achieves uniform temperature level of hot phosphoric acid solution L within processing tank 2 and thus, improves the controllability of etch amount during the etching process.

The third embodiment was based on an example in which a temperature drop of approximately 3.5 degrees Celsius was recovered when 50 wafers W were immersed in hot phosphoric acid solution L. The level of temperature drop varies with the number and thickness of wafer W or the processing temperature of wafer W and thus, the level of preemptive elevation in the temperature of hot phosphoric acid solution L may be modified as required.

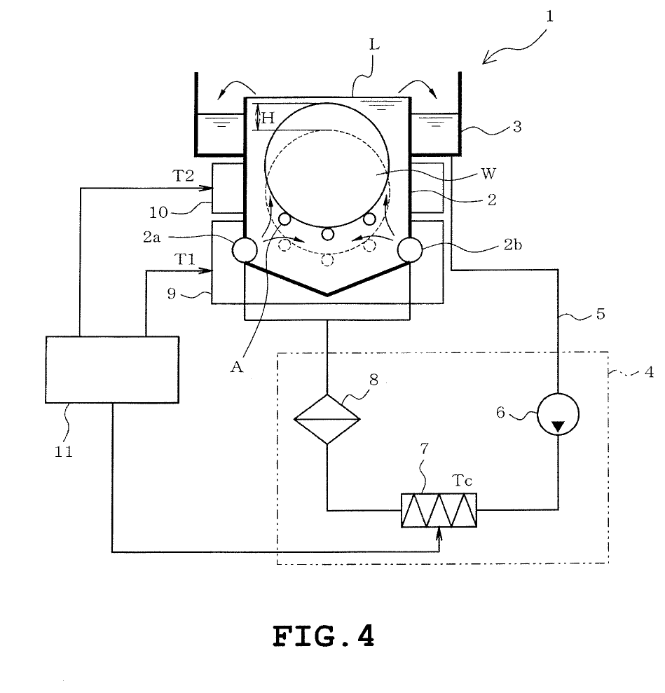

FIG. 4 illustrates a fourth embodiment. In the fourth embodiment, a method of processing a substrate is described through etching of a substrate using etching apparatus 1 described in the first embodiment or the second embodiment as was the case in the third embodiment.

As earlier described, wafer W, being carried by wafer lifter A is immersed in the bath of hot phosphoric acid solution L by being lowered to a predetermined depth within processing tank 2. In the fourth embodiment, wafer lifter A is lowered to a position higher by H from the predetermined position. H may range, for instance, from several millimeters to 2 centimeters. In this raised position, which is higher than the predetermined position normally employed, wafer W is completely submerged in the bath of hot phosphoric acid solution L within processing tank 2.

By immersing wafer W in the bath of hot phosphoric acid solution L with wafer lifter A raised by H from the normal position, the following effects can be obtained.

Firstly, wafer W is prevented from being exposed to the portion of hot phosphoric acid solution L of relatively high temperature by immersing wafer Win a position upwardly distanced from the bottom central portion located near the bottom surface of processing tank 2 where hot phosphoric acid solution L of relatively high temperature resides. Secondly, incoming hot phosphoric acid solution L from recirculation system 4, being discharged into processing tank 2 from discharge tubes 2a and 2b, can be impinged on the bars of wafer lifter A to be dispersed within processing tank 2. As a result, hot phosphoric acid solution L no longer stays at the bottom central portion near the bottom surface of processing tank 2 but instead contacts wafer W in a dispersed state. Thus, the silicon nitride film of wafer W can be etched with improved precision.

The foregoing embodiments may be expanded or modified as follows.

The above described apparatus and method may be applied to etching of films other than silicon nitride film formed on wafer W. Examples of such films may be insulating films such as a silicon oxide film, a silicon film, metal film, or the like.

Further, the workpiece substrate is not limited to a silicon substrate exemplified as wafer W in the foregoing embodiments but may be applied to various types of substrates.

In the foregoing embodiments, a couple of heaters, namely heaters 9 and 10 or heaters 12 and 10, have been exemplified as the multiple heaters being wound on the outer periphery of processing tank 2. Alternatively, 3 or more heaters may be applied to processing tank 2 so as to be distributed separately in the upper and lower portions of processing tank 2 as long the temperature setting of each heater can be controlled separately. In case the bottom surface of processing tank 2 is to be heated, a dedicated heater may be applied separately on the bottom surface.

The processing liquid is not limited to hot phosphoric acid solution L. Other types of etchant liquids and reactive liquids may be employed such as water used in hot water treatment that require uniformity in processing temperature.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of processing a substrate using a substrate processing apparatus including a processing tank that retains a processing liquid and that accommodates a workpiece substrate, a recirculation system recirculating the processing liquid into the processing tank by supplying the processing liquid heated by a recirculation system heater from a lower portion of the processing tank and collecting the processing liquid from an upper portion of the processing tank, a plurality of heaters distributed on an upper portion and a lower portion of the processing tank to heat the processing liquid, the method comprising:
setting a first temperature setpoint to a heater located on the upper portion of the processing tank; and
setting a second temperature setpoint lower than the first temperature setpoint to a heater located on the lower portion of the processing tank.

2. The method according to claim 1, wherein the workpiece substrate comprises a semiconductor substrate having a silicon nitride film formed thereabove and the processing liquid comprises a hot phosphoric acid solution.

3. The method according to claim 2, wherein the first temperature setpoint is 160 degrees Celsius and the second temperature setpoint is 0.5 to 1.5 degrees Celsius lower than the first temperature setpoint.

4. The method according to claim 1, wherein the substrate processing apparatus further includes a substrate placement for carrying the workpiece substrate into the processing tank, and wherein the substrate placement is carried into the processing liquid within the processing tank and retained at a position in which the processing liquid discharged into the processing tank impinges on the substrate placement and thereby dispersed within the processing tank.

5. The method according to claim 1, further comprising, prior to setting the first temperature setpoint:
preemptively setting a temperature setpoint of the plurality of heaters to be greater than a process temperature suitable for substrate processing depending on a count of workpiece substrates being processed, in anticipation of temperature drop occurring after the workpiece substrates are immersed into the processing tank, and
immersing the workpiece substrates into the processing tank.

6. A method of processing a substrate using a substrate processing apparatus including a processing tank that retains a processing liquid and that accommodates a workpiece substrate, a recirculation system recirculating the processing liquid into the processing tank by supplying the processing liquid heated by a recirculation system heater from a lower portion of the processing tank and collecting the processing liquid from an upper portion of the processing tank, a plurality of heaters distributed on an upper portion and a lower portion of the processing tank to heat the processing liquid, the method comprising:
setting a first temperature setpoint equal to a process temperature, in which the processing liquid processes the workpiece substrate within the processing tank, to a heater located on the upper portion of the processing tank, and
setting a second temperature setpoint lower than the first temperature setpoint to a heater located on the lower portion of the processing tank and the recirculation system heater.

7. The method according to claim 6, wherein the workpiece substrate comprises a semiconductor substrate having a silicon nitride film formed thereabove and the processing liquid comprises a hot phosphoric acid solution.

8. The method according to claim 7, wherein the first temperature setpoint is 160 degrees Celsius and the second temperature setpoint is 0.5 to 1.5 degrees Celsius lower than the first temperature setpoint.

9. The method according to claim 6, wherein the substrate processing apparatus further includes a substrate placement for carrying the workpiece substrate into the processing tank, and wherein the substrate placement is carried into the processing liquid within the processing tank and retained at a position in which the processing liquid discharged into the processing tank impinges on the substrate placement and thereby dispersed within the processing tank.

10. The method according to claim 6, further comprising, prior to setting the first temperature setpoint:
preemptively setting a temperature setpoint of the plurality of heaters to be greater than the process temperature suitable for substrate processing depending on a count of workpiece substrates being processed, in anticipation of temperature drop occurring after the workpiece substrates are immersed into the processing tank, and
immersing the workpiece substrates into the processing tank.

11. The method according to claim 6, wherein the processing tank is heated by the heater, located on the lower portion of the processing tank, from a bottom side and a sidewall side of the processing tank.

12. A substrate processing apparatus comprising:
a processing tank that retains a processing liquid and that accommodates a workpiece substrate;
a recirculation system recirculating the processing liquid into the processing tank by supplying the processing liquid heated by a recirculation system heater from a lower portion of the processing tank and collecting the processing liquid from an upper portion of the processing tank;
a plurality of heaters distributed on an upper portion and a lower portion of the processing tank and heating the processing liquid; and
a controller that controls heating of the plurality of heaters independently.

13. The apparatus according to claim 12, wherein a heater located on the lower portion of the processing tank heats the processing tank from a bottom side and a sidewall side of the processing tank.

14. The apparatus according to claim 12, wherein a heater distributed on the lower portion of the processing tank is located so as to heat the processing tank from a sidewall side of the processing tank and not from a bottom side of the processing tank.

15. The apparatus according to claim 12, wherein the controller sets a first temperature setpoint equal to a process temperature, in which the processing liquid processes the workpiece substrate within the processing tank, to a heater located on the upper portion of the processing tank, and a second temperature setpoint lower than the first temperature setpoint to a heater located on the lower portion of the processing tank and the recirculation system heater.

16. The apparatus according to claim 12, wherein the controller sets a first temperature setpoint to a heater located on the upper portion of the processing tank, and a second temperature setpoint to a heater located on the lower portion of the processing tank.

17. The apparatus according to claim 12, further comprising a collecting receptacle that is provided on an upper peripheral portion of the processing tank and that collects the processing liquid overflowing from the processing tank, and wherein the recirculation system is configured to receive the processing liquid from a bottom portion of the collecting receptacle.

18. The apparatus according to claim 12, wherein the plurality of heaters comprises a rubber heater.

19. The apparatus according to claim 12, wherein the processing tank comprises a quartz glass and the processing liquid comprises a hot phosphoric acid solution.

20. The apparatus according to claim 12, wherein the recirculation system includes discharge tubes that are provided on two opposing bottom ends of the processing tank and that discharge the processing liquid toward a bottom central portion of the processing tank.
